(19) United States
(12) Patent Application Publication
(10) Pub. No.: US 2025/0258984 A1
(43) Pub. Date: Aug. 14, 2025

(54) Language Servers for High-Level Synthesis

(71) Applicant: Microsemi SoC Corp., Chandler, AZ (US)

(72) Inventors: Jongsok Choi, Richmond Hill (CA); Adham Ragab, Oakville (CA); Stefan Scodellaro, Richmond Hill (CA); Muhammad Soliman, Toronto (CA)

(73) Assignee: Microsemi SoC Corp., Chandler, AZ (US)

(21) Appl. No.: 18/910,675

(22) Filed: Oct. 9, 2024

Related U.S. Application Data
(60) Provisional application No. 63/551,502, filed on Feb. 8, 2024.

(51) Int. Cl. G06F 30/327

(52) U.S. Cl. CPC G06F 30/327

(57) ABSTRACT

A non-transitory computer readable memory (CRM) is provided comprising instructions that, when executed on a processor, receive a request message from a source code editor including a location in an HLS design file and an autocompletion request, the HLS design file including at least one HLS command, identify zero or more tokens for the request, and generate a response message.

### RELATED APPLICATIONS

This application claims the benefit of U.S. Provisional Application No. 63/551,502 filed Feb. 8, 2024, which is incorporated herein in its entirety.

### FIELD OF THE INVENTION

The present application relates to systems and methods for developing and testing High-Level Synthesis (HLS) designs targeting system-on-chip (SOC) field programmable gate array (FPGA) devices.

### BACKGROUND

High-Level Synthesis (HLS) aims to make hardware design easier by raising the design abstraction of hardware to software. Hardware is often designed at the register-transfer level (RTL) using a hardware description language (HDL), Designing hardware at the RTL level is difficult, error-prone, and difficult to debug. Writing software is comparatively easier and is faster to compile and debug. HLS allows a software program described in a common programming language such as C or C++ to be compiled to HDL.

Although HLS aims to make hardware design easier, for HLS to generate high-performance hardware, users need to insert C++ pragmas or predefined Tcl commands to guide the HLS compiler how to translate the input software. The pragmas and predefined Tcl commands are examples of HLS guideposts necessary to allow conversion of high-level programming code into HDL. An example of a pragma may be “#pragma HLS loop pipeline”, which needs to be placed before a loop to indicate to that the loop needs to be pipelined. In this example, the first character is a hash character (i.e., ‘#’) followed immediately by the word “pragma.” An example of a Tcl command guidepost is “set_operation_latency <operation_name><latency_value>”, which sets a timing target for a particular type of operation.

The pragmas and Tcl commands need to be in a specific format and be specified at the correct location. There are lots of pragmas and Tcl commands available, and without the use of proper pragmas and Tcl commands, HLS compiler cannot translate the software into a hardware configuration. This makes HLS difficult to use, as it can be challenging for users to know which pragmas and Tcl command to use, what format they should be used in, and what effect they will have on the generated hardware. A typical process for users to understand this is to read through hundreds of pages of documentation, which is time consuming, error-prone, and difficult to understand. This results in a significant investment for a new HLS user to use the approach efficiently. Because of this difficult learning curve, only advanced users have been able to fully utilize the power of HLS optimizations. There is a need to aid users applying HLS to HDL design.

### SUMMARY

In some examples, a non-transitory computer readable memory (CRM) is provided comprising instructions that, when executed on a processor, receive a request message from a source code editor including a location in an HLS design file and an autocompletion request, the HLS design file including at least one HLS command, identify zero or more tokens for the request, and generate a response message. The message contains at least one of a description corresponding to the zero or more tokens, a list of valid HLS commands, a proper HLS syntax prompt, and a prompt for an HLS pragma. In some examples, the CRM includes instructions that when executed on the processor identify an HLS command token in the line of source code as part of the request message, and generate the response message to include the HLS command token and a list of zero or more required arguments. In some examples, the zero or more tokens includes one token comprising a hash character, and the response message contains the prompt for the HLS pragma. In some examples, the HLS design file contains C or C++ code, and wherein the CRM comprises instructions that when executed on the processor identify a pragma token followed by an HLS token, and identify a partial HLS pragma token following the HLS token, and generate the response message includes identifying a subset of the list of valid HLS commands matching the identified partial HLS command token. In some examples, the identified zero or more tokens includes a valid HLS command that requires a program variable and the CRM comprising instructions that when executed on a processor identify a list of program variables defined in the HLS design file, and append the proper HLS syntax prompt with the list of valid options. In some examples, the valid HLS command requires the parameter argument to be of one or more allowed parameter types, the CRM comprises instructions that when executed on a processor eliminate from the list of defined parameters all parameters not matching the allowed parameter types. In some examples, the CRM comprises instructions that when executed on a processor identify a syntax error and send the response message to include an error message.

In some examples, a CRM comprises instructions that when executed on a processor establish a socket connection with a source code editor, receive over the socket connection an edit notification referencing an HLS design file, parse a first line of the HLS design file to generate a first list of tokens, identify one of the first list of tokens as an HLS command, identify an error in the first list of tokens, include an error message in a diagnostics list, and send the diagnostics list over the socket to the source code editor. In some examples, the CRM comprises instructions that when executed on the processor identify the HLS command as an invalid command, and include a valid HLS command suggestion in the diagnostics list. In some examples, the CRM comprises instructions that when executed on the processor retrieve an expected number of parameters for the HLS command, determine the first list of tokens contains fewer than the expected number of parameters for the HLS command, and include an incomplete command message in the diagnostics list. In some examples, the CRM comprises instructions that when executed on the processor determine the first list of tokens contains an invalid parameter for the HLS command, and include an invalid parameter message in the diagnostics list. In some examples, the CRM comprises instructions that when executed on the processor determine the first list of tokens contains a parameter of an invalid type for the HLS guidepost, and include an invalid parameter type message in the diagnostics list. In some examples, the CRM comprises that when executed on the processor parse each remaining non-empty line of the HLS design file. In some examples, the error message includes a line number in the HLS design file.

In some examples, the CRM comprises instructions that when executed on a processor receive a request message from a source code editor including a location specifying a line number and a character number within an HLS design file, the HLS design file including at least one HLS command, retrieve a line of source code from the HLS design file at the specified line number, tokenize the retrieved line of source code from the HLS design file, identify a token in the tokenized line of source code corresponding to the character number, and generate a response message containing a description of the identified token. In some examples, the CRM comprises that when executed on the processor determine the request message indicates a hover request, and including documentation of the identified token in the response message. In some examples, the CRM comprises instructions that when executed on the processor determine the identified token is a hash character, and including a prompt for an HLS pragma in the response message. In some examples, the CRM comprises instructions that when executed on the processor identify the token is a partial HLS command, identify a list of valid HLS guidepost matching the partial HLS command, and include the list of matching HLS commands in the response message. In some examples, the CRM comprises instructions that when executed on the processor determining the token is an HLS command that requires a parameter, identify a match list of program variables defined in the HLS design file, and include the match list in the response message. In some examples, the CRM includes instructions that when executed on the processor determining the required parameter is designated to be a specified type, and excluding from the match list of program variables any program variable with a type different than the specified type.

### BRIEF DESCRIPTION OF THE DRAWINGS

FIGS. 1-22 are screenshots of an integrated development environment operating in conjunction with HLS Language Servers, according to certain examples of the present disclosure.

FIGS. 23-30 are flowcharts illustrating the operation of HLS Language Servers, according to certain examples of the present disclosure.

### DETAILED DESCRIPTION

Examples provided use HLS Language Servers to assist users in navigating the HLS language elements and in understanding their proper usage. In some examples, an integrated development environment interacts with a language server via the open, standardized Language Server Protocol (LSP). LSP operates over JSON-RPC (JavaScript Object Notation Remote Procedure Call).

In one example, an HLS language server is provided for C++ pragmas (HLSC). HLSC is responsible for handling the HLS C++ pragmas and works on C and C++ files. C and C++ are commonly used, general purpose computer programming languages. In another example, an HLS language server is provided for Tool Command Language (Tcl) commands (HLST). The HLST is responsible for handling the HLS Tcl commands and works on Tcl files. Tcl is a commonly used, general purpose computer programming language. Both language servers serve the same goal of making HLS design easier and provide similar functionalities in terms of autocompletion, syntax checking, linting, and documentation. Autocompletion means that as user starts typing a pragma or a Tcl command, the respective language server will figure out what the user is intending to type and show a list of valid options. In some examples, the options may be sorted by a match ranking. As the user types more, the listed options will continue to narrow down. When user presses the ‘tab’ key, the language server will automatically fill out the pragma or Tcl command with the first listed autocomplete option. Thus, users do not need to type the full pragma or Tcl command, speeding up development, and do not need to remember the complete syntax/format of complex pragmas and Tcl commands. Further, as the user becomes more proficient with pragmas and/or Tcl commands for HLS, the user may type more and rely on autocompletion less as the HLS server may provide context specific information without impeding the user's typing.

Documentation of pragmas and commands are also shown as a user autocompletes them, or if they hover the mouse cursor over completed commands/pragmas. With this, user can easily and quickly understand the command/pragma, without having to search through many pages of documentation.

Real-time syntax checking for pragmas/commands is provided before the software is even compiled, giving early feedback to users. Responsive messages may suggest alternatives or close approximations of commands based on what has been typed. Responsive messages may offer correct alternatives to the erroneous pragmas and Tcl commands users have written to help them fix the issues. Lastly, the HLSC provides real-time linting for C/C++ code to alert the user portions of code that cannot be compiled to HLS hardware.

HLS Language Servers such as HLST and HLSC improve user experience through autocompletion, hover over documentation, syntax checking, and linting. HLS Language Servers may require read access to one or more source code files. These files may be registered with the HLS Language Server to provide read access. For example, an IDE may register the current source code file with an HLS Language Server by providing a uniform resource locator (URL) as a path to the file. In another example, an IDE may provide a source code repository file identifier and version number.

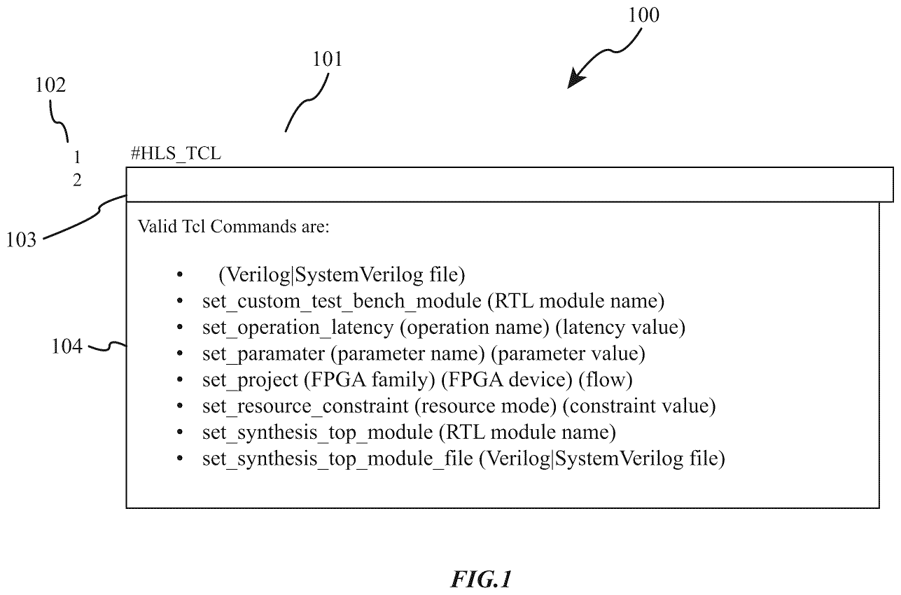

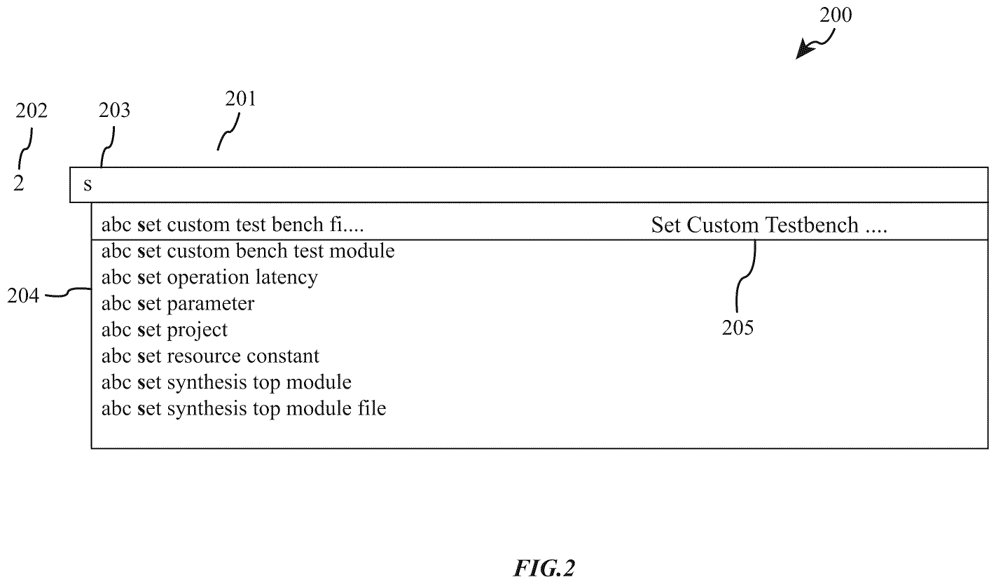

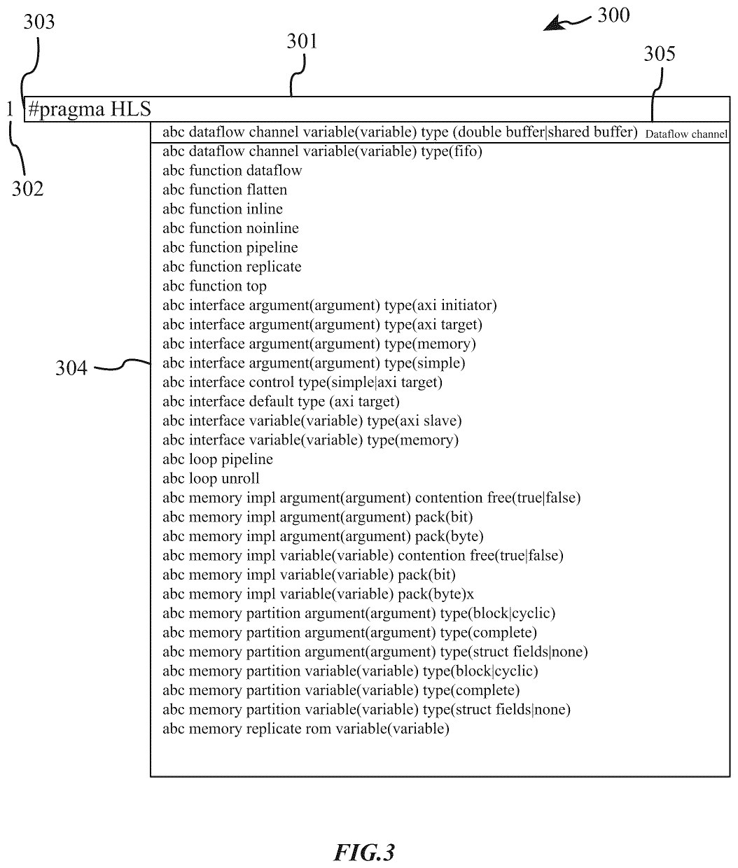

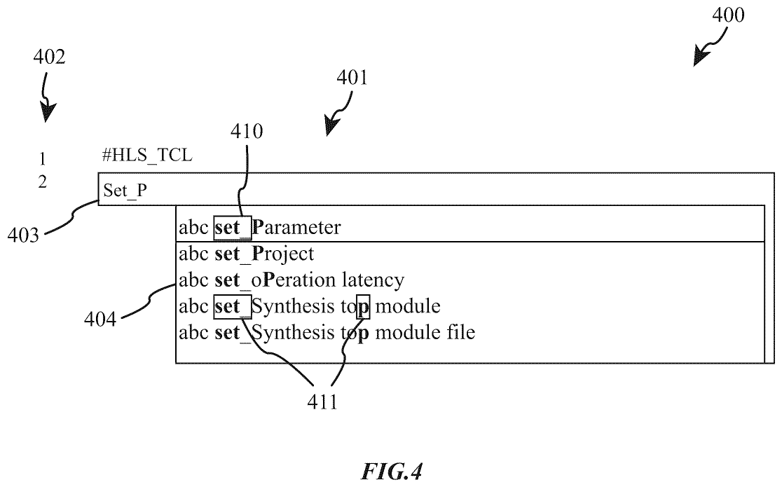

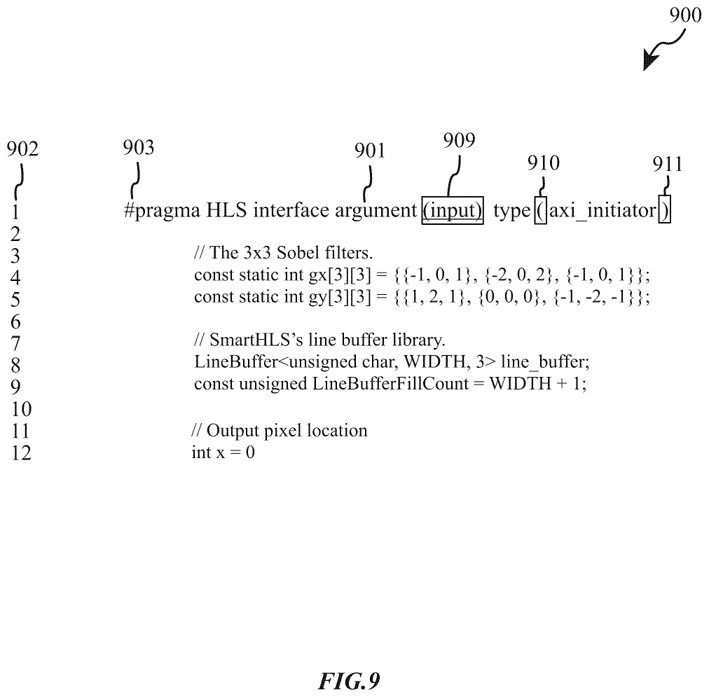

Autocompletion: HLST and HLSC display possible Tcl commands (FIGS. 1-2) and C++ Pragmas (FIG. 3) with their expected structures. As a user starts typing, the servers display the possible commands/pragmas filtered based on the characters the user has typed (FIGS. 4-8). The servers provide snippets to show the fields that need to be filled in (FIGS. 9-12). If the field receives pre-defined options, it shows the valid options as a dropdown (FIG. 11). If the field is for a user-defined variable that is a function argument, the HLSC server can check that the filled in variable is a valid function argument and return a response message identifying and describing the error (FIG. 9).

FIG. 1 illustrates an IDE interface, according to certain examples. IDE interface 100 displays lines of code 101, each paired with a corresponding line number 102. For example, line 1 of the source code file reads “#HLS_TCL” and signals to a compiler that this source code is written in the Tcl language and is intended to be compiled into a hardware design through high-level synthesis (HLS). Current source code line 103 is blank. Autocomplete message box 104 extends from current source code line 103 and provides a message listing one or more valid Tcl commands the user may type.

FIG. 2 illustrates an IDE interface, according to certain examples. IDE interface 200 displays lines of TCL code 201, each paired with a corresponding line number 202. Current source code line 203 consists of the single letter “s”. Autocomplete message box 204 extends from current source code line 203 and provides a message listing one or more valid Tcl commands the user may type filtered by commands starting with the letter “s”. Autocomplete message box 204 also provides additional syntax information 205 corresponding to the first listed autocomplete command.

FIG. 3 illustrates an IDE interface, according to certain examples. IDE interface 300 displays lines of C/C++ code 301, each paired with a corresponding line number 302. Current source code line 303 consists of the pragma statement “#pragma HLS” that signals to a compiler the code following the pragma statement is to be compiled into a hardware design through HLS. Autocomplete message box 304 extends from current source code line 303 and provides a message listing one or more valid pragma statements and additional information link 305. Pragma statements listed in autocomplete message box 304 may include a type identifier (e.g., dataflow channel) and a listing of arguments. In some examples, the IDE may prepend “abc” to each autocomplete message returned from the language server.

FIG. 4 illustrates an IDE interface, according to certain examples. IDE interface 400 displays lines of TCL code 401, each paired with a corresponding line number 402. Current source code line 403 consists of the letters “Set_P”. Autocomplete message box 404 extends from current source code line 403 and provides a message listing one or more valid Tcl commands the user may type. The language server may parse the “Set_P” into “Set_” and “P” or “Set” and “P” recognizing that “Set” or “Set_” is a prefix for many commands. The language server may predict the user may be attempting to type a command starting with “Set_P” or may be attempting to type a command starting “Set” and including a “p” later in the command name. In some examples, emphasis 410 may be applied to occurrences of “Set_P” in the autocomplete message. In some examples, the system may split the string into tokens at the underscore character and emphasis 411 may be applied to occurrences of tokens “set” and “p” are bolded or otherwise emphasized in the list of autocomplete commands. This emphasis may aid the user in determining why each autocomplete list entry was presented.

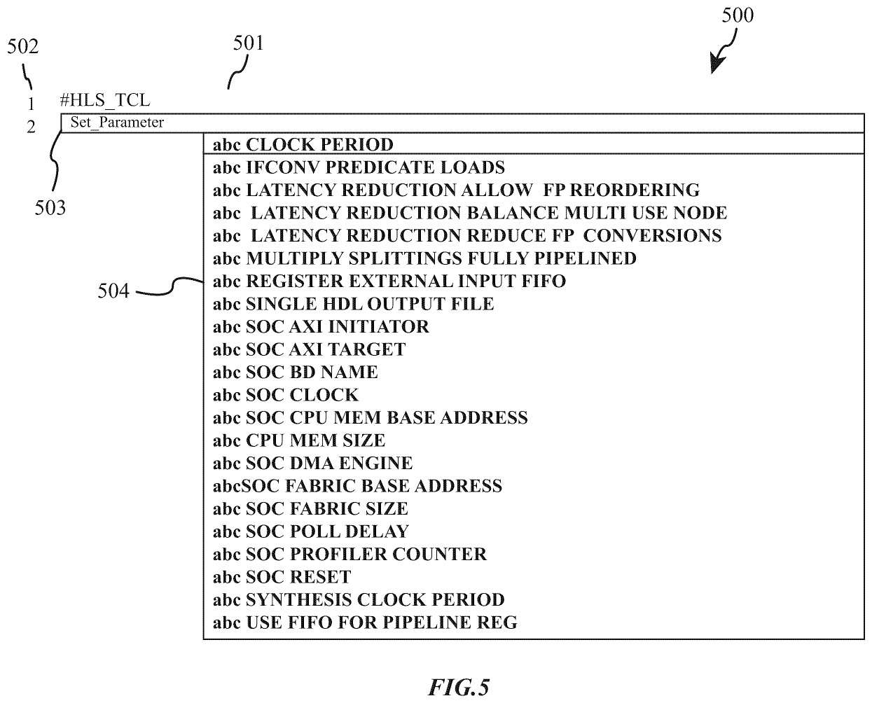

FIG. 5 illustrates an IDE interface, according to certain examples. IDE interface 500 displays lines of TCL code 501, each paired with a corresponding line number 502. Current source code line 503 consists of the letters “Set_Parameter”. Autocomplete message box 504 extends from current source code line 503. The IDE may recognize “Set_Parameter” as a TCL command for setting a parameter value. The language server may then generate a list of parameters defined in the source code file (and any included header or library files). Autocomplete message box 504 may then list the parameters (or subset of parameters along with a scrollbar). In some examples, if the user were to type “Set_Parameter LAT” the IDE may further filter the list to the three entries with “LATENCY” in the parameter name.

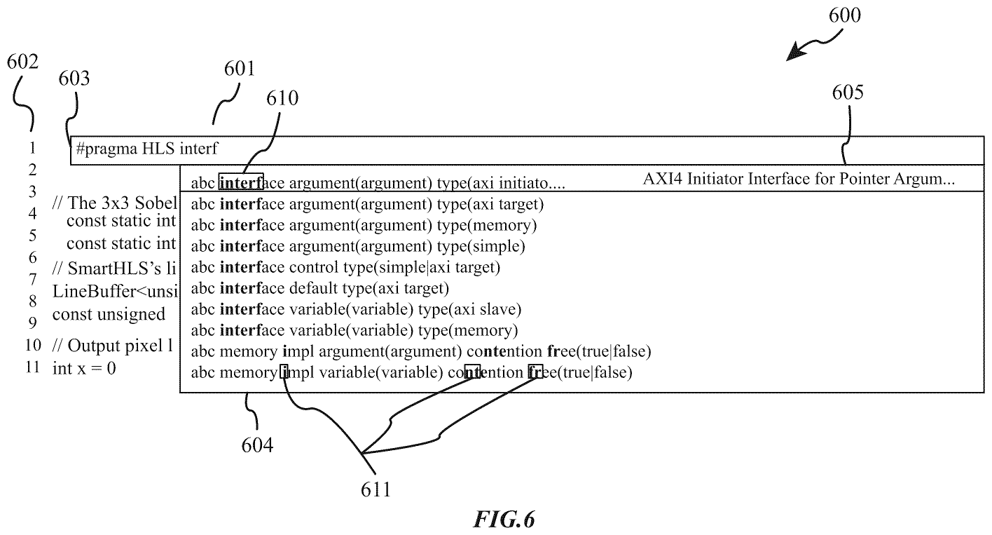

FIG. 6 illustrates an IDE interface, according to certain examples. IDE interface 600 displays lines of C/C++ code 601, each paired with a corresponding line number 602. Current source code line 603 consists of the pragma statement and a partial pragma specifier, i.e., “#pragma HLS interf”. Autocomplete message box 604 extends from current source code line 603 and provides a message listing one or more valid pragma statements and additional information link 605. Pragma statements listed in autocomplete message box 604 may be filtered to start with “interf”. In some examples, pragma statements listed in autocomplete message box 604 may be filtered to include the letters in “interf” such as partial match 611. IDE interface 600 may bold or otherwise emphasize the matching letters to provide context to the programmer.

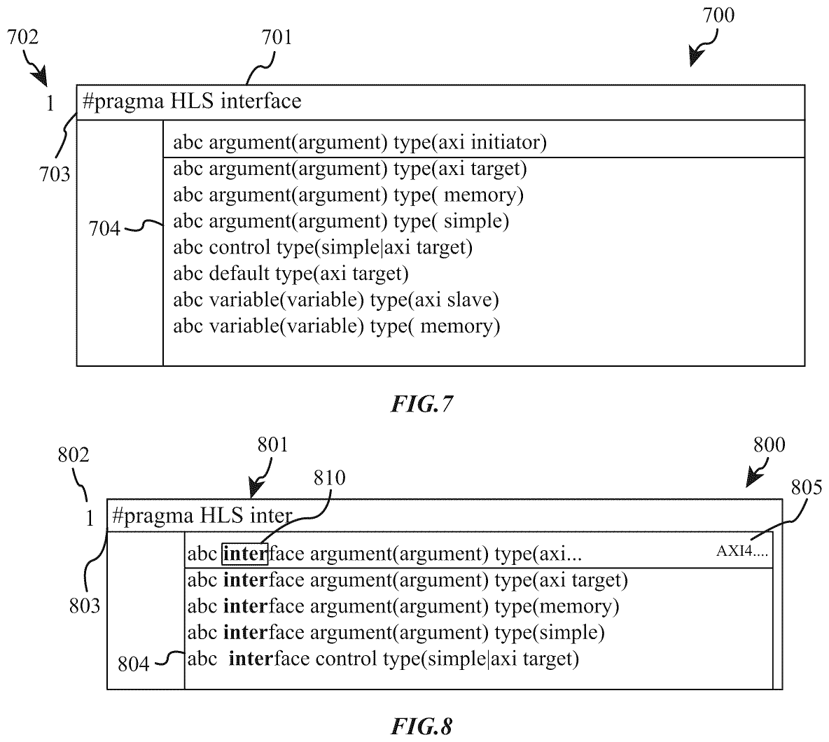

FIG. 7 illustrates an IDE interface, according to certain examples. IDE interface 700 displays lines of C/C++ code 701, each paired with a corresponding line number 702. Current source code line 703 consists of the pragma statement and a partial pragma specifier, i.e., “#pragma HLS interface”. Autocomplete message box 704 extends from current source code line 703 and provides a message listing one or more autocomplete options. Because the language server recognizes “interface” as an interface pragma, the language server provides a list of relevant autocomplete options for an interface pragma. For example, an interface might be an argument of type AXI initiator.

FIG. 8 illustrates an IDE interface, according to certain examples. IDE interface 800 displays lines of C/C++ code 801, each paired with a corresponding line number 802. Current source code line 803 consists of the pragma statement and a partial pragma specifier, i.e., “#pragma HLS inter”. Autocomplete message box 804 extends from current source code line 803 and provides a message listing one or more autocomplete options. Because the language server recognizes “interf” as a partial interface pragma, the language server provides a list of relevant autocomplete options beginning with those letters to be displayed in autocomplete message box 804. Emphasis 810 may be applied to occurrences of the string “interf” in autocomplete message box 804. Autocomplete message box 804 may also include a link to more information 805 corresponding to the first autocomplete option. In some examples, a user may select a different autocomplete option and the language server may provide a link to more information for the selected autocomplete option. If the programmer (user) selects the first autocomplete option, the language server will provide emphasis as shown in FIG. 9.

FIG. 9 illustrates an IDE interface, according to certain examples. IDE interface 900 displays lines of C/C++ code 901, each paired with a corresponding line number 902. Current source code line 903 consists of the pragma statement and an incomplete pragma specifier, i.e., “#pragma HLS interface argument (input) type (axi_initiator)”. Here the programmer has partially specified the argument as “input.” The language server added emphasis 909 to the partially specified argument thus prodding the programmer to complete the specification of that argument. The language server also added emphasis 910 and emphasis 911 to the parenthesis around the type “axi_initiator” thus prodding the programmer to double check that interface type. The language server is provided the cursor location within current line 903 and thus knows the programmer is still editing in the middle of the line and has not yet advanced the cursor to the type field.

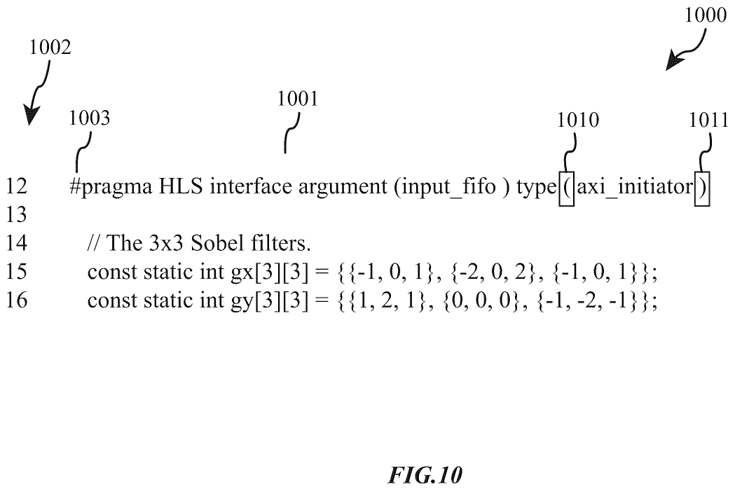

FIG. 10 illustrates an IDE interface, according to certain examples. IDE interface 1000 displays lines of C/C++ code 1001, each paired with a corresponding line number 1002. Current source code line 1003 consists of the pragma statement and a pragma specifier, i.e., “#pragma HLS interface argument (input_fifo) type (axi_initiator)”. Here the programmer has fully specified the argument as “input_fifo” but still has not advanced the cursor to the type field. The language server added emphasis 1010 and emphasis 1011 to the parenthesis around the type “axi_initiator” thus prodding the programmer to double check that interface type.

FIG. 11 illustrates an IDE interface, according to certain examples. IDE interface 1100 displays lines of C/C++ code 1101, each paired with a corresponding line number 1102. Current source code line 1103 consists of the pragma statement and a partial pragma specifier, i.e., “#pragma HLS interface control t”. Autocomplete message box 1104 lists a single autocomplete option “abc type (simple|axi target)” with emphasis on the “t” in “type” to provide context to the programmer of the reason the autocomplete list included this entry.

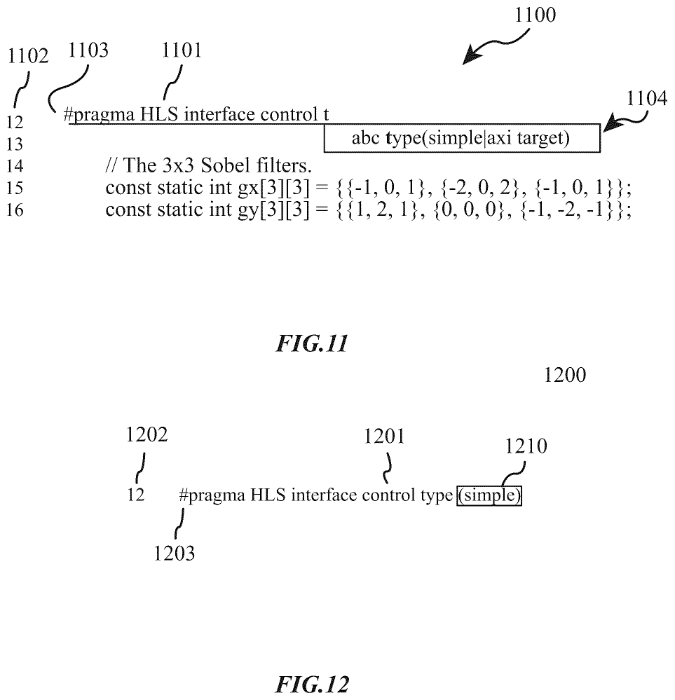

FIG. 12 illustrates an IDE interface, according to certain examples. IDE interface 1200 displays lines of C/C++ code 1201, each paired with a corresponding line number 1202. Current source code line 1203 consists of the pragma statement and a partial pragma specifier, i.e., “#pragma HLS interface control type(simple)” where “(simple)” has been emphasized to signal to the programmer the need to validate the control type. Emphasis 1210 may be applied to occurrences of the string “simple” to draw the programmer's attention to this argument, which may be “simple” or “axi_target” in this example.

### Examples of Documentation and Error Checking

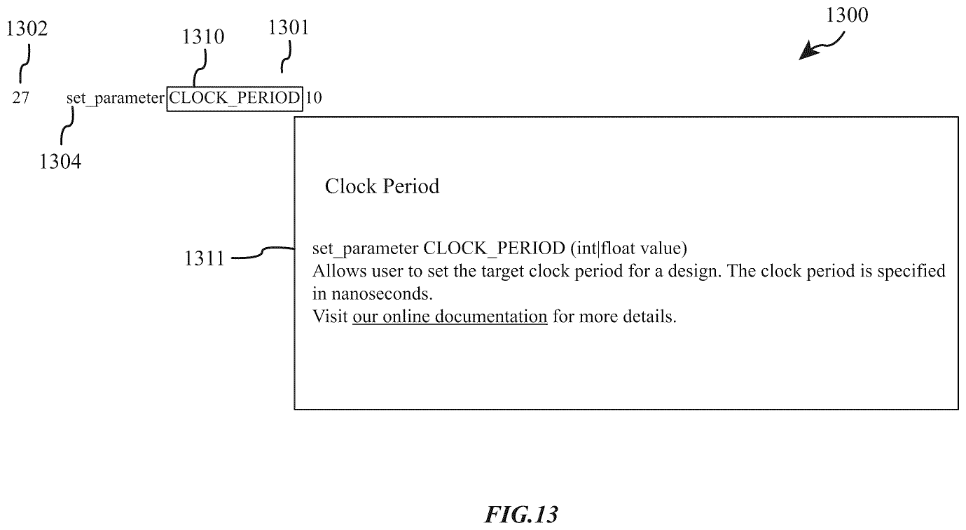

Hover Over Documentation: In some examples, the system will recognize when a programmer hovers the mouse over Tcl commands/pragmas and will display documentation (also displayed during autocompletion) describing what commands/pragmas do and how different parameters affect the generated hardware (examples are illustrated in FIGS. 13-15).

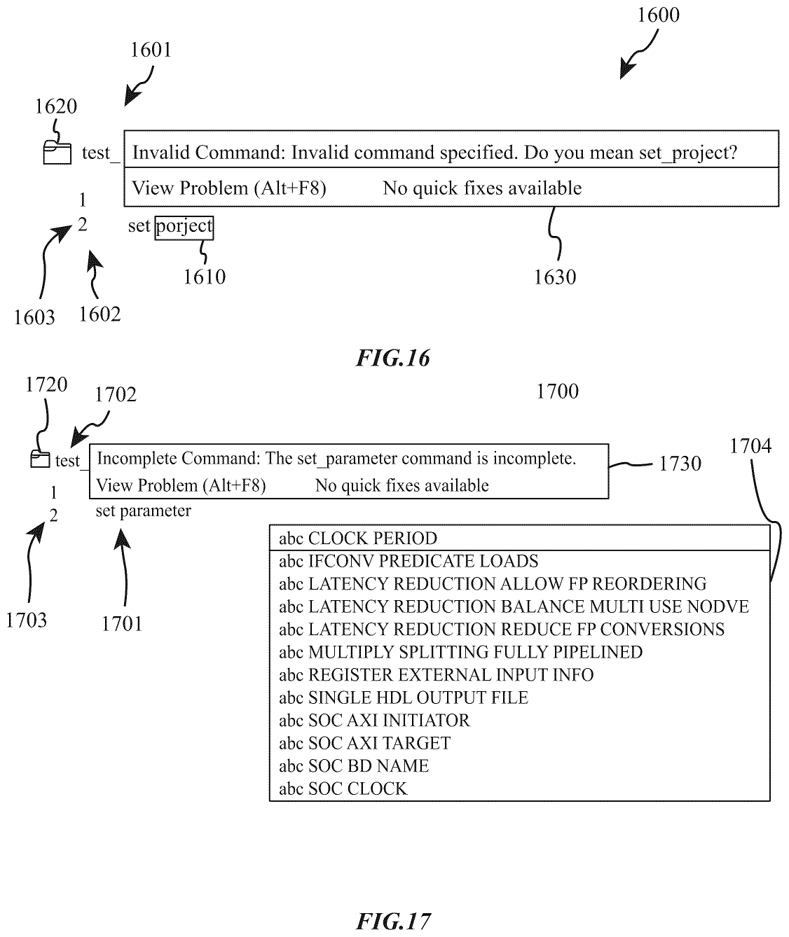

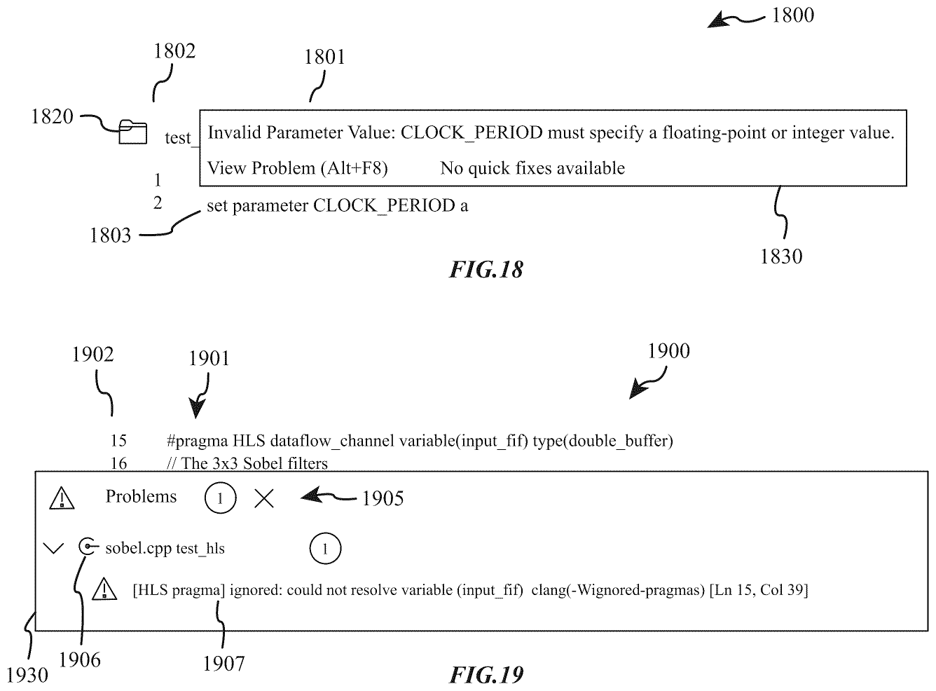

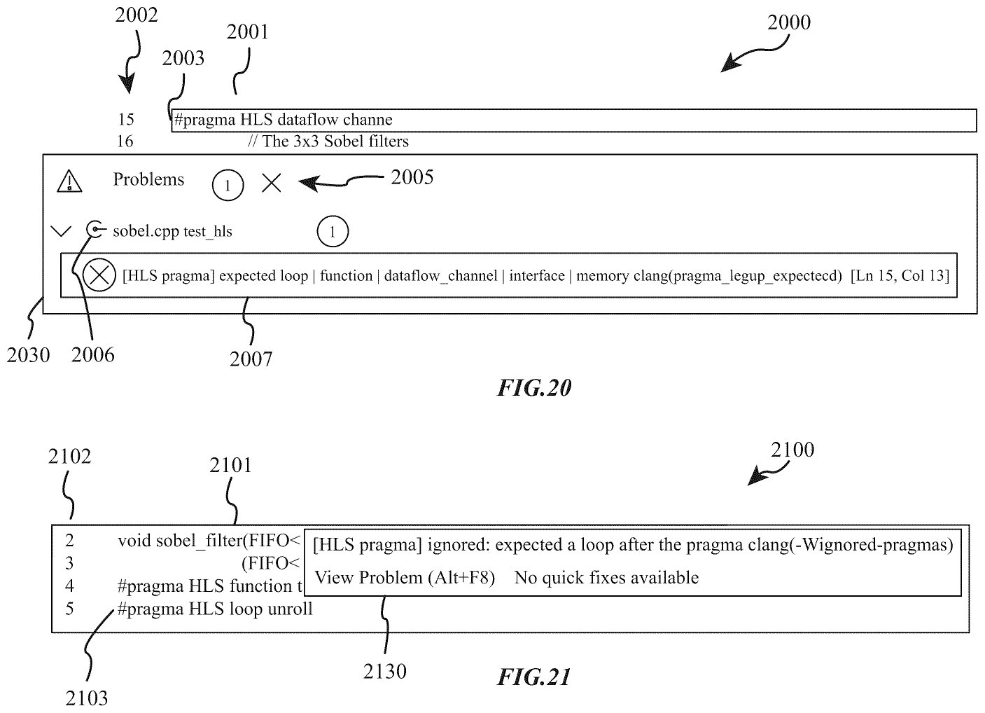

Syntax Checking: In some examples, the system will check for syntax. Any mistyped Tcl commands may be emphasized (e.g., red-lined), with a possible fix suggested (FIG. 16). When commands are incomplete, users may be notified (FIG. 17). Upon an incorrect command parameter, a message describing the expected type/value may be shown (FIG. 18). Some HLS pragmas take in variable names, which may be noted if the variable is undefined (FIG. 19). Any errors may be shown in real-time, with valid options shown to the user (FIG. 20). Certain pragmas must be used in specific places in the code (e.g., before a loop), which may be highlighted if used incorrectly (FIG. 21).

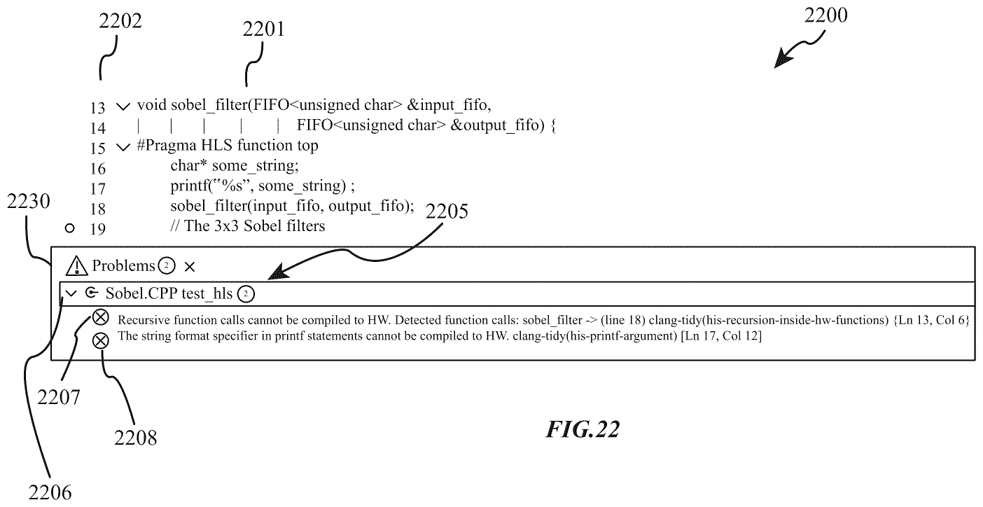

Linting: In some examples, checks may be performed to validate whether constructions may be compiled into hardware. In some examples, certain C/C++ constructs cannot be compiled to hardware (FIG. 22). Linting checks may be implemented using Clang-Tidy, which may take in the source code in its AST (Abstract Syntax Tree) form and analyze the AST if any unsupported constructs are used. Warnings and errors may be shown to the user in real-time, giving early feedback even before the code is compiled.

HLST and HLSC may feature a client (the IDE where the user is writing code) and servers communicating asynchronously using the JSON-RPC protocol. JSON-RPC is a remote procedure call (RPC) protocol encoded in JSON.

In some examples, clients send messages as requests for actions (e.g. autocompletion) or notifications of an update within the client (e.g. new open file). Servers may respond to client requests with the output of a service if successful or an error state otherwise.

Servers may not need to respond to notifications but may choose to do some action in receipt of certain notifications (e.g. file edits triggering syntax checking).

FIG. 13 illustrates an IDE interface, according to certain examples. IDE interface 1300 displays lines of Tcl code 1301, each paired with a corresponding line number 1302. Current source code line 1304 consists of a statement setting a parameter value. The parameter name, “CLOCK_PERIOD”, has an overlay area 1310 illustrating a hover-over region. Pop-up box 1311 appears when the programmer hovers over (or in some examples clicks) within overlay area 1310. Pop-up box 1311 provides information about the clock period parameter.

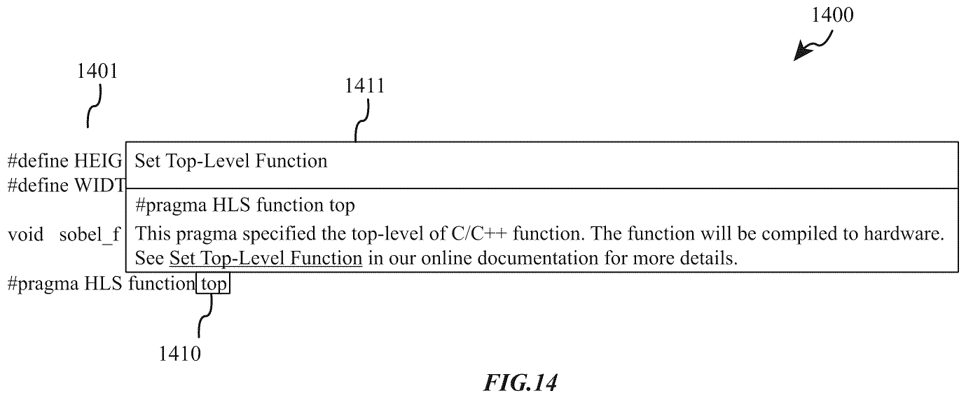

FIG. 14 illustrates an IDE interface, according to certain examples. IDE interface 1400 displays lines of C/C++ code 1401. When a user hovers over the word “top” the user interface applies emphasis 1410 in a pragma definition, pop-up box 1411 may provide information about a “top-level function” declaration. In some examples, the language server determines that the word “top” only appears in the “function” category of pragmas.

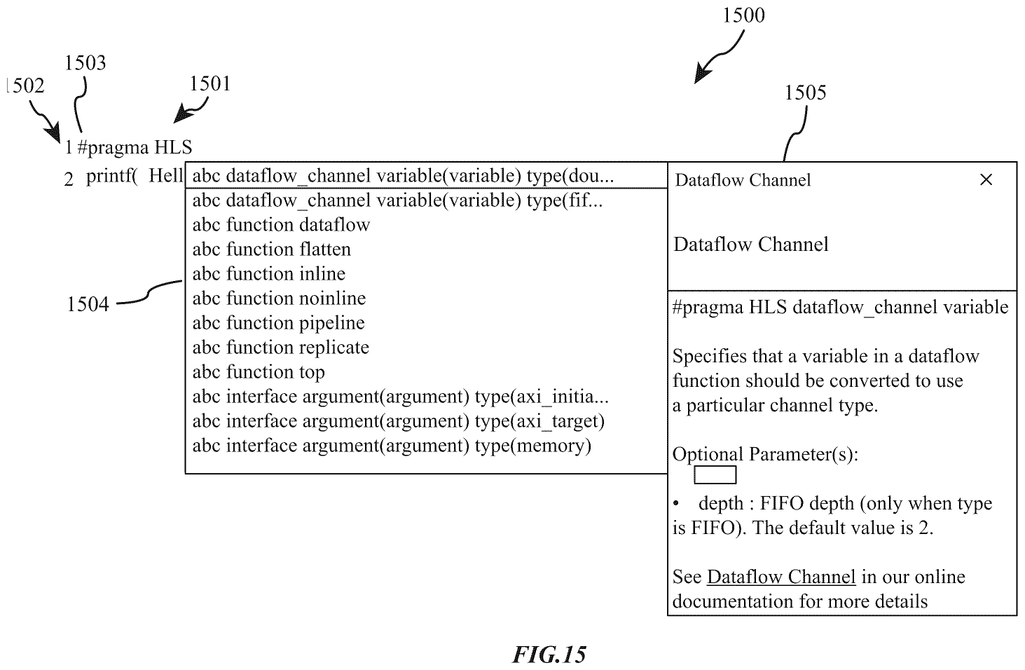

FIG. 15 illustrates an IDE interface, according to certain examples. IDE interface 1500 displays lines of C/C++ code 1501, each paired with a corresponding line number 1502. Current source code line 1503 consists of the pragma statement without any additional specification. Autocomplete message box 1504 lists autocomplete options. Detail box 1505 provides additional information about the first (or a selected) autocomplete option.

FIG. 16 illustrates an IDE interface, according to certain examples. IDE interface 1600 displays lines of high-level source code 1601 in source code file 1620. IDE interface 1600 displays each line of source code with its corresponding line number 1602. Current source code line 1603 consists of a misspelled command: “set project”. The language server indicates a problem with the misspelled word with emphasis 1610 and providing a message for display in pop-up error message 1630.

FIG. 17 illustrates an IDE interface, according to certain examples. IDE interface 1700 displays lines of high-level source code 1701 in source code file 1720. IDE interface 1700 displays each line of source code with its corresponding line number 1702. Current source code line 1703 consists of an incomplete command: “set parameter”. The language server indicates a problem with the incomplete command providing a message for display in pop-up error message 1730. In addition, autocomplete message box 1704 lists available parameters to be set with the “set parameter” command.

FIG. 18 illustrates an IDE interface, according to certain examples. IDE interface 1800 displays lines of high-level source code 1801 in source code file 1820. IDE interface 1800 displays each line of source code with its corresponding line number 1802. Current source code line 1803 consists of an erroneous command: “set parameter CLOCK_PERIOD a”. The language server indicates a problem with the erroneous command providing a message for display in pop-up error message 1830.

FIG. 19 illustrates an IDE interface, according to certain examples. IDE interface 1900 displays lines of high-level source code 1901. IDE interface 1900 displays each line of source code with its corresponding line number 1902. Source code 1901 includes a reference to an undefined variable “input_fif”. The language server indicates a problem with the erroneous command providing a message for display in pop-up error message 1930. Pop-up error message 1930 identifies a count of problems in the code 1905. File indicator 1906 indicates the name of the source code file. Problem message 1907 describes the problem as an unresolved variable name and identifies the source code line and column number where the problem can be found.

FIG. 20 illustrates an IDE interface, according to certain examples. IDE interface 2000 displays lines of high-level source code 2001 with corresponding line numbers 2002. Source code 2001 includes an incomplete pragma statement “dataflow_channe” in current line 2003. The language server indicates a problem with the erroneous command providing a message for display in pop-up error message 2030. Pop-up error message 2030 identifies a count of problems in the code 2005. File indicator 2006 indicates the name of the source code file. Problem message 2007 describes the problem as an invalid HLS pragma.

FIG. 21 illustrates an IDE interface, according to certain examples. IDE interface 2100 displays lines of high-level source code 2101 with corresponding line numbers 2102. Source code 2101 includes a pragma statement “loop unroll” in current line 2103. The language server indicates a problem with the context of the command providing a message for display in pop-up error message 2130. Pop-up error message 2130 explains that the “loop unroll” pragma must be immediately followed by a loop construct such as FOR, WHILE, or DO . . . WHILE.

FIG. 22 illustrates an IDE interface, according to certain examples. IDE interface 2200 displays lines of high-level source code 2201. IDE interface 2200 displays each line of source code with its corresponding line number 2202. The language server indicates a problem with two errors providing a message for display in pop-up error message 2230. Pop-up error message 2230 identifies a count of problems 2205 in source code file 2206. First problem message 2207 explains that recursive function calls cannot be compiled into hardware. Second problem message 2208 explains that print formatting cannot be compiled into hardware.

### HLST Autocompletion

In some examples, autocompletion for HLST is triggered when a user engages with a Tcl file, e.g., starts a new command or inserts a space. The client dispatches a JSON-RPC request to HLST with the line and character number where the user's cursor is located.

Upon receiving this request, the server retrieves the line and tokenizes the active command, parsing the user's input into tokens separated by whitespace, facilitating subsequent analysis of user's input.

If the active command is empty (new file/line), the server generates an autocompletion list with all Tcl commands, complete with their syntax structures and any associated documentation, and sends it in a JSON-RPC response to the client for the users to choose from.

Otherwise, the server first verifies the initial token as a valid Tcl command. If successful, the server then examines the command's completeness-whether the number of tokens meets the expected count for a full command. In case of an incomplete command, the server dynamically generates a list of suggestions based on previously examined tokens.

For each subsequent token, the server refines its suggestions, aiming to provide the most relevant options. If at any point a token does not correspond to a valid command or parameter, the server dispatches an empty list, signaling to the user that the input does not match any preexisting Tcl commands.

The server's response each time is sent back to the client, which then displays these suggestions users to select from the autocomplete options. The autocomplete options also contain snippets, which either allow users to choose between a predetermined set of values for a given parameter or fill in a variable/argument name supplied to a parameter.

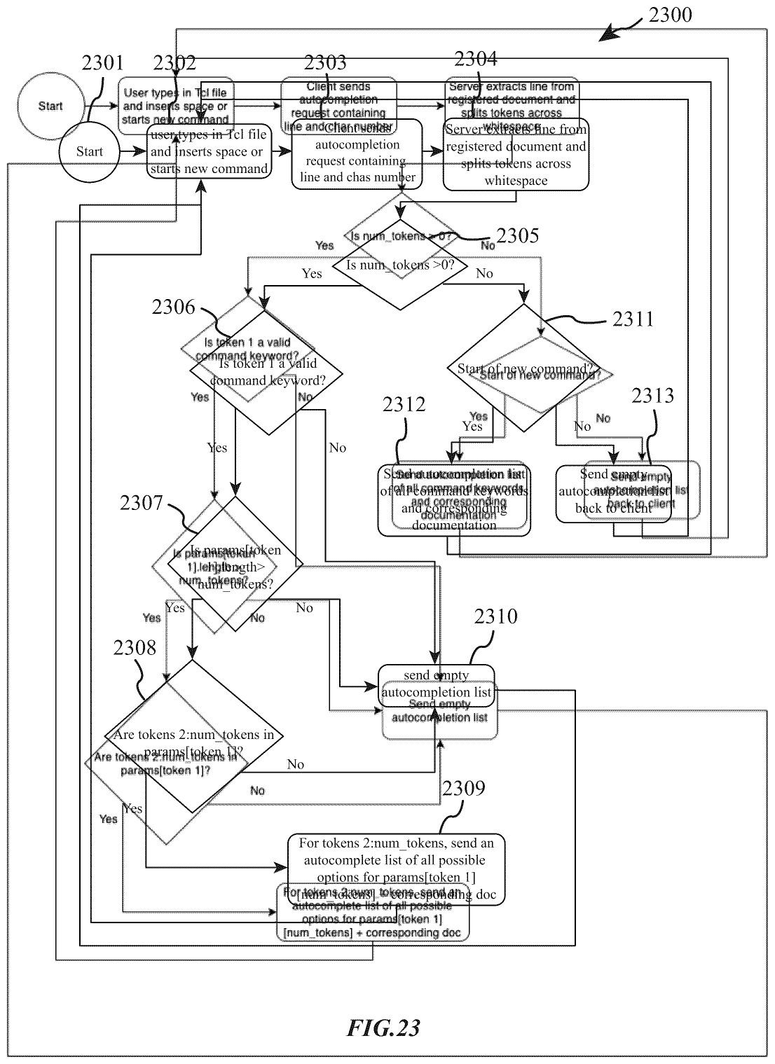

FIG. 23 illustrates a method for performing autocompletion for HLST, according to certain examples. Method 2300 begins at block 2301. At block 2302, a user types in a Tcl file and inserts a space or starts a new command. At block 2303, the client software sends an autocompletion request containing the line and character number of the cursor. At block 2304, the server extracts the line of code from the registered source code file and splits the line at each whitespace character to generate a list of tokens (e.g., contiguous sequences of letters or numbers). At block 2305, the server determines whether any tokens were found in the line. If no, the method continues at block 2311. If yes, at block 2306, the server determines whether the first token is a valid command keyword. If no, the method continues to block 2310. If yes, at block 2307, the server determines whether the parameters required for the command keyword (of the first token) is greater than the number of additional tokens in the current line of source code. If no, the method continues to block 2310. If yes, at block 2308, the server determines whether the parameters for the command of the first token match the remaining tokens (e.g., tokens 2:num_tokens). If no, the method continues to block 2310. If yes, at block 2309, the server processes each remaining token (beyond the first token) and generates an autocomplete list of all possible options for parameters for the command keyword. In some examples, the server also provides corresponding documentation. The server sends this autocomplete list and (in some examples) corresponding documentation to the client for display in the IDE and the method continues at block 2302. At block 2310, the server sends the client an empty autocompletion list and the method continues at block 2302.

If the number of tokens at block 2305 is not greater than zero, the method continues to block 2311. No tokens may be determined if the line contains no whitespace characters (e.g., space, tab). No tokens may be determined if the line contains a whitespace character preceded by empty tokens. At block 2311, the server determines whether the current line is the start of a new command. For example, a line with no whitespace characters to parse may indicate the start of a new command. If yes, at block 2312, the server sends the client an autocompletion list of all command keywords and, in some examples, corresponding documentation. If no, at block 2313, the server sends the client an empty autocompletion list back to the client. In both cases, the method continues at block 2302.

### HLSC Autocompletion

Autocompletion for HLSC may be triggered when a user types a space or the “#” symbol at the start of a line in a C/C++ file. The client sends an autocompletion request with the line and character number where the user's cursor is located.

The server receives this request and extracts the relevant line from the document, breaking it down into tokens based on whitespace. If only a “#” token is detected, the server suggests “pragma HLS” as the autocompletion entry to start a new pragma. If there are additional tokens, the server consults its database of pragmas, comparing the tokens against predefined patterns using regular expressions. When a match is found, and if subsequent documentation is available for the matched pragma, it is attached to the autocompletion suggestion.

The server iteratively constructs and refines the autocompletion list with each new token to keep suggestions relevant and accurate. Upon deviation from predefined pragmas, the server returns an empty list, prompting the developer to reconsider their input. Once the server has a finalized list of autocompletion suggestions, it sends this list back to the client in a JSON-RPC response.

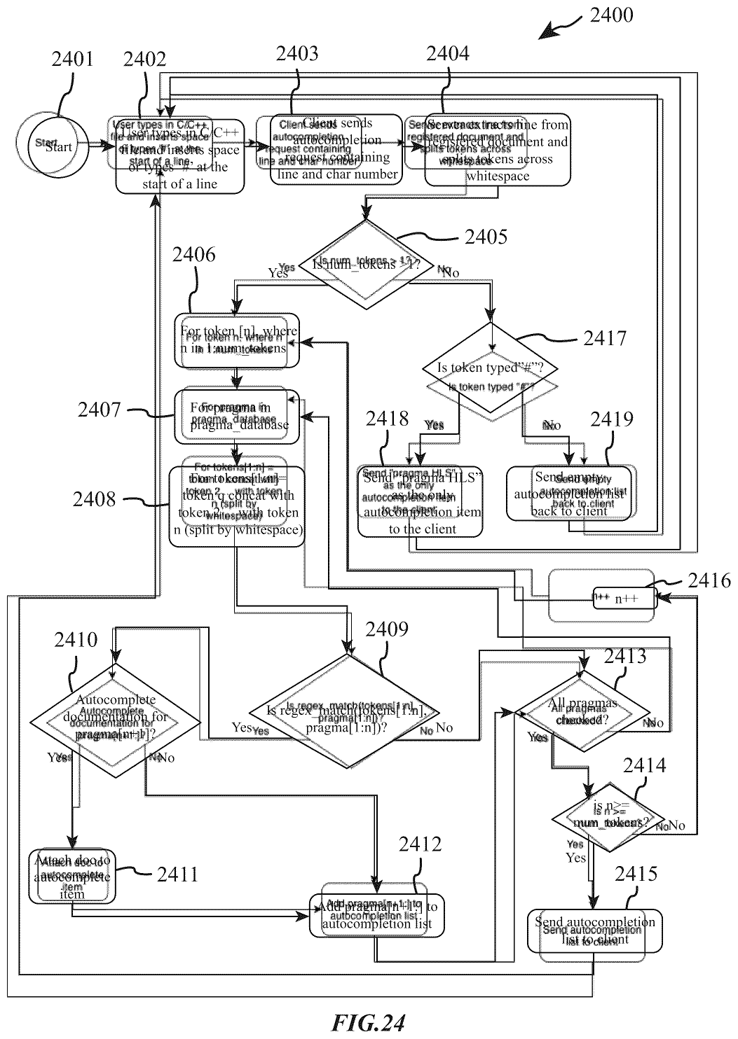

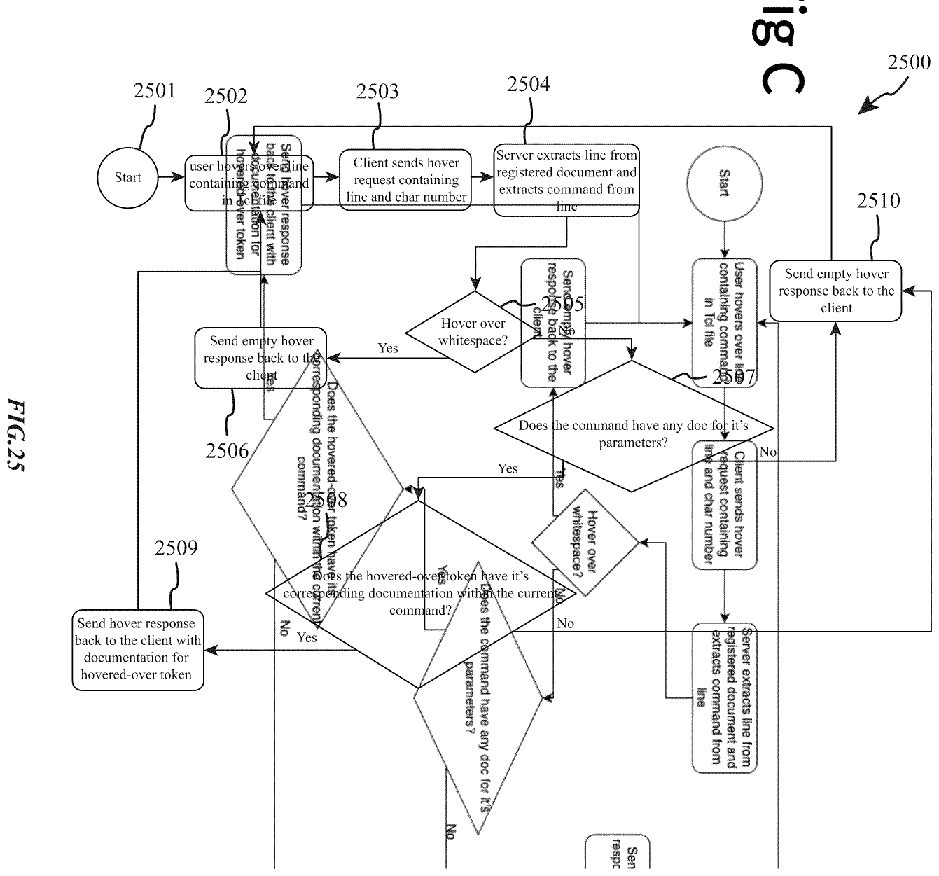

FIG. 24 illustrates a method for performing autocompletion for HLSC, according to certain examples. Method 2400 begins at block 2401. At block 2402, the user types in a C/C++ file and inserts a space or types a ‘#’ at the start of a line. At block 2403, the client sends an autocompletion request to the server containing the line and character number of the cursor. At block 2404, the server extracts the line of source code from the registered source code file and splits the line based on whitespace into non-whitespace tokens. At block 2405, the server determines whether more than one token exists. If yes, at block 2406, the server begins processing each of n tokens. At block 2407, the server loops over each pragma defined in a pragma database. At block 2408, the server concatenates tokens 1 through n with defined whitespace to allow string comparison with the predefined pragmas. At block 2409, the server performs a string comparison (e.g., a regular expression or regex comparison) of the output of block 2408 and an entry in the pragma list from the pragma database. If no, the method continues to block 2413.

If yes at block 2409, then at block 2410 the server checks for the existence of documentation for pragma [n+1:]. If no, the method continues to block 2412. If yes, at block 2411, the server attaches autocomplete documentation to the autocomplete item record (e.g., sourced from pragma [n+1:]) and continues to block 2412. At block 2412, the server adds autocomplete item record to the autocompletion list. At block 2413, the server checks to see if each pragma has been checked. If not, the method returns to block 2406. If yes, at block 2414, the server checks to see if n is greater or equal to the number of tokens identified at block 2404. If yes, at block 2415, the server sends the autocompletion list to the client and the method returns to block 2402. If no, at block 2416 n is incremented and the method returns to block 2406.

If no at block 2405, at block 2417 the server checks if the token is a hash character (i.e., ‘#’). If yes, at block 2418, the server sends “pragma HLS” as the only autocompletion item to the client and the method returns to block 2402. If no, at block 2419, the server sends an empty autocompletion list back to the client and the method returns to block 2402.

### HLST Hover Over Documentation

In some examples, when a user navigates the cursor over a Tcl command, this triggers a hover event. The client sends a hover JSON-RPC request containing the line and character number that the cursor is on.

Upon receipt of this request, the server locates the specific line from the Tcl document and proceeds to analyze the content.

If the cursor is placed over whitespace, the server promptly responds with an empty hover response, signaling no relevant documentation.

Otherwise, when the user hovers over a specific token within a command, the server determines whether that token has corresponding documentation. If such documentation exists, the server packages it into a JSON-RPC response and sends it back to the client.

This hover response includes the detailed documentation for the hovered-over token, enabling the user to gain insights into the command's functionality without the need to refer to external documentation. If the token lacks associated documentation, or if the command itself does not have parameter documentation, an empty response is returned instead.

This interaction does not just stop at a single token, but instead applies to each part of the command as the user hovers over them.

FIG. 25 illustrates a method for performing autocompletion for HLST, according to certain examples. Method 2500 begins at block 2501. At block 2502, the user hovers over a line containing a command in a Tcl file. At block 2503, the client software sends a hover request containing the line and character number corresponding to the mouse hover location. At block 2504, the server extracts the line of source code from the registered document and extracts the Tcl command from the line of source code. At block 2505, the server determines whether the hover location is whitespace. If yes, at block 2506, the server sends an empty hover response back to the client and the method returns to block 2502. If no, at block 2507, the server determines whether a documentation database has any documentation for the command extracted at block 2504. If yes, at block 2508, the server determines whether the hovered-over token has corresponding documentation within the current command. If yes, at block 2509, the server sends a hover response back to the client with documentation for the hovered-over token and the method returns to block 2502. If no, at block 2510, the server sends an empty hover response back to the client and the method continues to block 2502.

### HLSC Hover Over Documentation

In some examples, when a user hovers their cursor over a line of code in a C/C++ file that contains a pragma, the client initiates a hover process for HLSC. The client communicates a hover JSON-RPC request to the HLSC indicating the line and character number where the cursor is positioned.

Upon receipt of the request, the server proceeds to extract the corresponding line from the document. It conducts a preliminary check to determine if the cursor is positioned over whitespace, returning an empty list to signal the absence of documentation.

When hovering over a non-whitespace (i.e., text), the server trims any leading or trailing whitespace to assess the content of the line. The server calculates the number of tokens present on the line and determines whether the number is equal to or greater than the threshold at which an HLS pragma can be distinctly recognized and differentiated. In some examples, that threshold is four tokens.

The server compares each token against its database of pragmas, which involves a regex match to ensure that the tokens align with the pattern of a preexisting pragma up to the Nth token. If the regex confirms a match, implying that the hovered text corresponds to a recognized pragma, the server fetches the associated documentation for that pragma.

The language server then packages this documentation into a hover response and relays it back to the client. If the regex fails to match any pragmas in the database-indicating that the hovered text does not correspond to any supported pragma-the server returns an empty hover response.

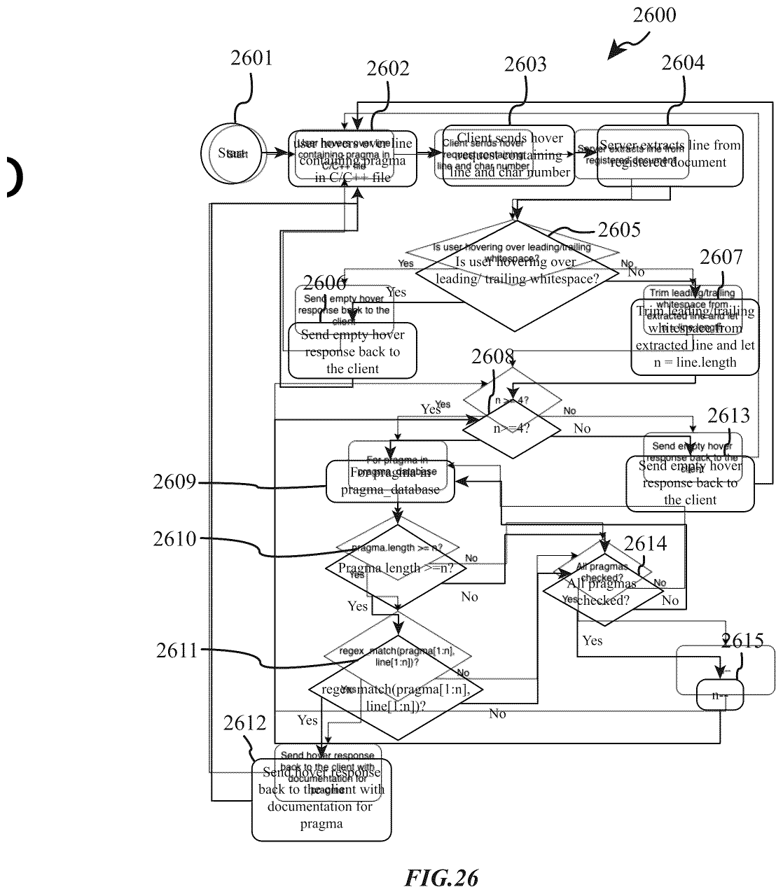

FIG. 26 illustrates a method for performing autocompletion for HLSC, according to certain examples. Method 2600 begins at block 2601. At block 2602, the user hovers over a line containing a pragma in a C/C++ file. At block 2603, the client sends a hover request containing the line and character number corresponding to the hover location. At block 2604, the server extracts the corresponding line of source code from the registered document. At block 2605, the server determines whether the user is hovering over leading/trailing whitespace. If yes, at block 2606, the server returns to the client an empty hover response back to the client. If no, at block 2607, the server trims the leading/trailing whitespace from the extracted line of source code and sets a variable n to the length of the extracted line of source code. At block 2608, the server determines whether n is greater or equal to four. If not, at block 2613, the server returns an empty hover response back to the client and the method returns to block 2602. If yes, at block 2609, a set of valid pragmas is retrieved from a pragma database and the method begins processing each retrieved pragma. At block 2610, the server determines whether the length of the current pragma from the retrieved list is compared to n. If the length of the current pragma is greater than n, the method proceeds to block 2611 and it no it proceeds to block 2614. At block 2611, the server performs a string comparison of the current pragma [1:n] and the extracted line of source code [1:n]. If the comparison is a match, at block 2612, the server returns a hover response back to the client with documentation for the current pragma. If the comparison is not a match, the method continues to block 2614, at block 2614, the server determines whether all pragmas retrieved from the pragma database have been checked. If not, the method returns to block 2609 to process the next pragma. If yes, the at block 2615, n is decremented by one and the method continues to block 2608.

### HLST Syntax Check

In some examples, when a user edits a Tcl file, the client captures and transmits the modifications to the server as a JSON-RPC notification. This notification prompts the HLST to engage in syntax checking.

The server retrieves the complete text, parsing it line by line and then word by word on each line, to analyze each command's structure and syntax. It first verifies the validity of each command keyword against a database of supported Tcl commands. If a keyword is mistyped, the server, utilizing a shortest-distance correction algorithm, suggests an alternative as part of the generated diagnostic message. Incomplete commands with valid keywords are similarly indicated, guiding the user to complete the necessary syntax correctly.

Parameters, which come after the command, are then validated, highlighting any parameter that deviates from the expected syntax and generating a corrective suggestion. Parameter values are also examined for type validity, with any errors included in the generated diagnostic list, which is subsequently communicated back to the client.

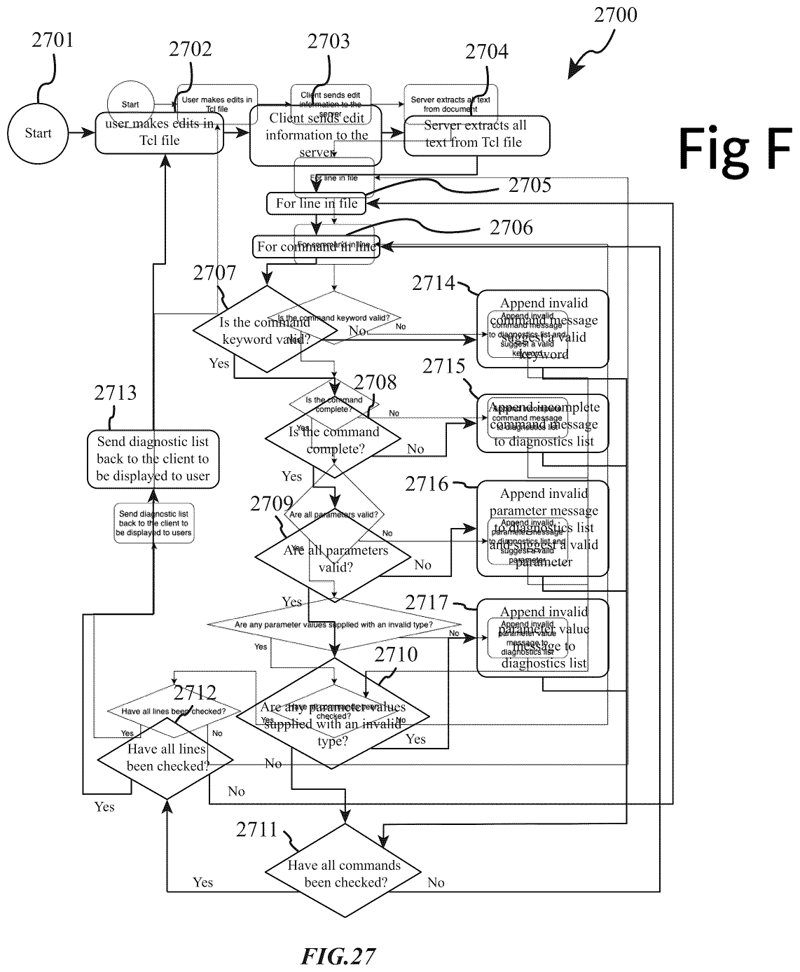

FIG. 27 illustrates a method of performing a syntax check, according to certain examples. Method 2700 begins at block 2701. At block 2702, the user makes edits in a Tcl file that is registered with the HLST server. At block 2703, the client sends edit information to the server. At block 2704, the server extracts all text from the registered Tcl file. At block 2705, the server begins processing each line in the registered Tcl file beginning with the first line as a current line for processing. At block 2706, the server parses for commands in the current line and begins processing each command beginning with the first command as a current command for processing. At block 2707, the server determines whether the current command contains a valid keyword. If yes, the method continues to block 2708. If no, at block 2714, the server appends an invalid command message suggesting a valid keyword and the method proceeds to block 2711.

At block 2708, the server determines whether the command is complete, e.g., the minimum number of parameters have been specified. If yes, the method continues to block 2709. If no, at block 2715, the server appends an incomplete command message to a list of diagnostics and the method proceeds to block 2711. At block 2709, the server determines whether all parameters to the command are valid. If the result of block 2709 is yes, the method continues to block 2710. If no, at block 2716, the server appends an invalid parameter message to the diagnostics list and suggests a valid parameter and the method continues to block 2711. At block 2710, the server determines whether any supplied parameters have an invalid type or an incompatible type. If no, the method continues to block 2711. If yes, at block 2717, the server appends an invalid parameter value message to the diagnostics list and the method continues to block 2711. At block 2711, the server determines whether all commands have been checked in the current line of code. If no, the method returns to block 2706 where the next command is processed as the current command. If yes, at block 2712, the server determines whether all lines of the Tcl file have been checked. If no, the method returns to block 2705 where the next line is processed as the current line. If yes, at block 2713 the server sends the diagnostic list back to the client to be displayed to the user.

### HLSC Syntax Check

In some examples, when a user edits in a C/C++ file, any modifications related to HLS pragmas initiate a syntax-checking process. The client detects these changes and sends the relevant edit information to the Clangd language server, which has been augmented with a pragma-specific Domain-Specific Language (DSL) engine dedicated to HLS pragmas. The Clangd language server was developed by the LLVM project to assist developers of C/C++ code by providing code completion, compile errors, and go-to-definitions of code elements.

Within the Clangd language server, any edits involving an HLS pragma pass through the HLS Pragma DSL engine, which tokenizes the pragma-each token associated with a specific feature or category as defined by the DSL's syntax.

The DSL engine's task is to validate the pragma according to these syntax rules, ensuring each token aligns correctly with the expected syntax. This involves checking that the parameters are spelled correctly, the features and categories are compatible, and the parameter values and types are valid. If any part of the pragma does not conform to the syntax rules, the DSL engine is designed to generate precise error messages.

These error messages are appended to a diagnostics list that the Clangd server compiles, encompassing both errors from the DSL engine and Clangd's standard diagnostics for C/C++ syntax. This diagnostics list is then sent back to the client, which displays it to the user.

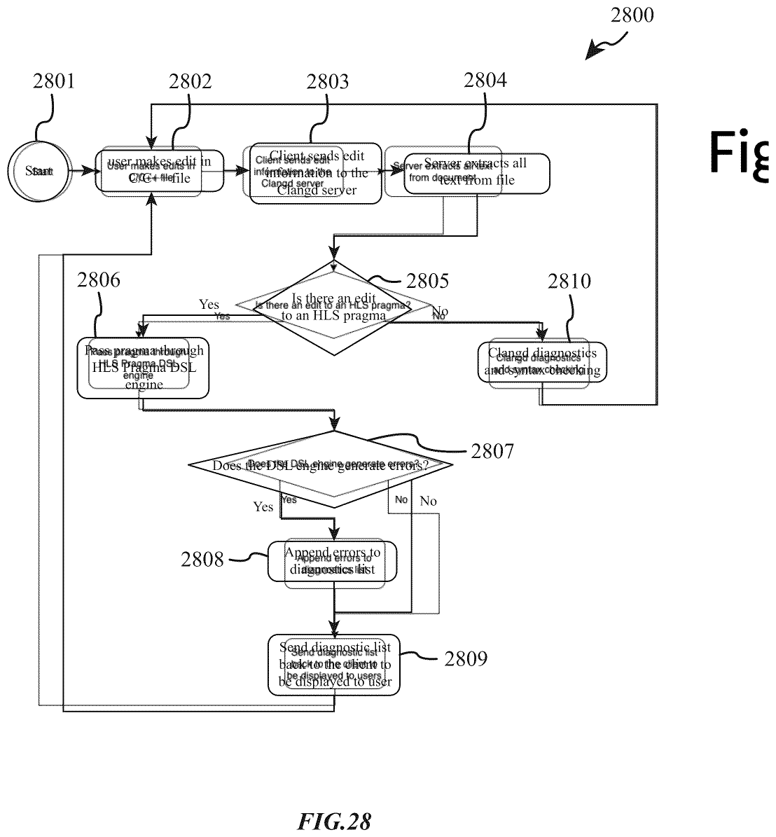

FIG. 28 illustrates a method of performing a syntax check, according to certain examples. Method 2800 begins at block 2801. At block 2802, a user makes an edit in a C/C++ file. At block 2803, the client sends edit information to the Clangd server. At block 2804, the server extracts all text from the source code file. At block 2805, the server determines whether there is an edit to an HLS pragma in the source code file. If no, at block 2810, the server performs Clangd diagnostics and syntax checking before the method returns to block 2802. If yes, at block 2806, the server passes the pragma through the HLS Pragma DSL engine. At block 2807, the server determines whether the DSL engine generated any errors. If no, the method proceeds to block 2809. If yes, at block 2808, the server appends errors to a diagnostics list. At block 2809, the server sends the diagnostic list back to the client to be displayed to the user and the method returns to block 2802.

### HLS C/C++ Linting Checks

In some examples, HLS linting checks are implemented within Clang-tidy, LLVM's clang-based linting framework. This tool allows for easy definition of an extensible set of checks to be embedded within and run alongside the Clangd language server. These checks are defined based on unsupported constructs, or rules to be adhered to, in order to effectively generate circuits using HLS.

While Clangd is running, clang-tidy is invoked on the open file. For each enabled linting check, the user's source code is first converted into its Abstract Syntax Tree (AST) representation using an instance of the Clang compiler. We first run a matcher to look for candidate sections of codes (AST nodes) for our checks, decided based on a set of attributes/conditions that apply (e.g. checks for unsized array arguments required matching AST nodes representing user-defined HW functions). This is done by traversing the AST and checking each node until all AST nodes have been visited, with matches added to a set of matched nodes. Following the matcher, a checker runs on each matched node, applying a list of tests defined for each check to verify the AST node. Any failures are noted and error messages are appended to the diagnostics list to be sent back to the client (the IDE) upon completion of all checks.

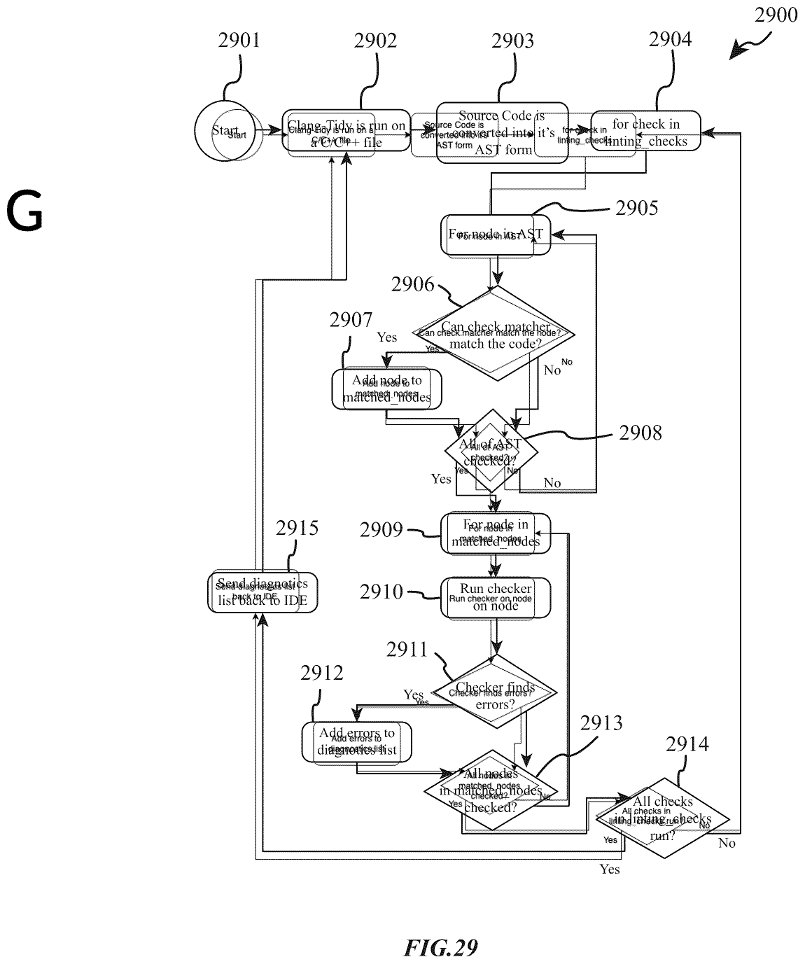

FIG. 29 illustrates a method of performing checks of programmatic and style errors, according to certain examples. Method 2900 begins at block 2901. At block 2902, the server invokes a linting tool on the C/C++ source code file. At block 2903, the linting tool converts the source code into AST form. At block 2904, the server retrieves a set of lint checks to perform from the linting_checks database and selects one as a current lint check. At block 2905, the method selects a node of the AST form of the source code file as the current node. At block 2906, the server determines whether the current node matches a set of search criteria by running the matcher method of the current lint check. If yes, at block 2907 the server adds the current node to a set of matched nodes and the method proceeds to block 2908. If no, the method proceeds to block 2908. At block 2908, the server determines whether each AST node has been checked. If not, the method returns to block 2905 to check another node. If yes, at block 2909, the server selects one of the matched nodes as the current node. At block 2910, the server runs a checker on the current node. At block 2911, the server determines whether errors were identified by the checker. If no, the method proceeds to block 2913. If yes, at block 2912, the server adds the errors to a diagnostics list and the method proceeds to block 2913. At block 2913, the server determines whether all matched nodes have been checked. If no, the method returns to block 2909 to process the next matched node. If yes, at block 2914, the server determines whether all linting checks have been completed. If no, the method returns to block 2904 to select the next linting check as a current linting check. If yes, at block 2915, the server sends the diagnostics list back to the client to display to the user.

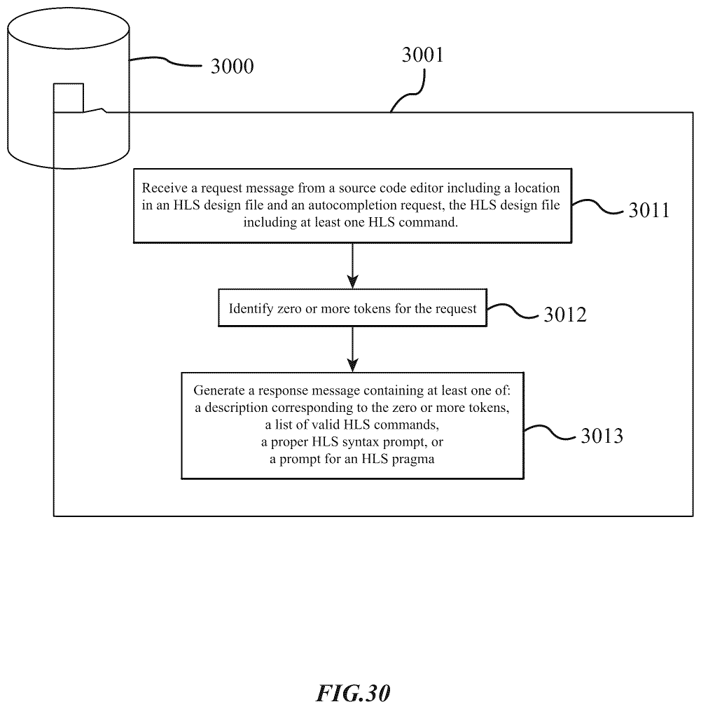

FIG. 30 illustrates a non-transitory computer readable memory comprising instructions for performing a method, according to certain examples. Non-transitory computer readable memory (“CRM”) 3000 may be a computer drive or network drive comprising instructions to be executed on a computer processor. CRM 3000 may comprise one or more files containing computer instructions that when executed on a process perform certain actions. CRM 3000 may include instructions 3011 to receive a request message from a source code editor including a location in an HLS design file and an autocompletion request, the HLS design file including at least one HLS command. CRM 3000 may include instructions 3012 to identify zero or more tokens for the request. CRM 3000 may include instructions 3013 to generate a response message containing at least one of a description corresponding to the zero or more tokens, a list of valid HLS commands, a proper HLS syntax prompt, or a prompt for an HLS pragma. In some examples, CRM 3000 includes instructions for performing actions described elsewhere in this disclosure.

Software for implementing the HLS Language Servers may be written in any number of programming languages and may execute as a script or compiled code. This software may be stored on a non-transitory computer readable memory such as a non-volatile computer drive. In some examples, the HLS Language Server may be installed on the same computer as the IDE and source code files. In other examples, the HLS Language Server may be accessible by the IDE over a network. In some examples, the HLS Language Server may be executing from random access memory (RAM) and executing within a browser on a personal computer. In some examples, the HLS Language Server software may be downloaded over a network and installed locally.

Although example embodiments have been described above, other variations and embodiments may be made from this disclosure without departing from the spirit and scope of these embodiments. Recitation of “a” or “the” processor is not intended to limit the claims to a single processor as some instructions may be executed on different processors without departing from this disclosure. For example, some instructions may be executed in different threads or processes that may communicate via shared memory or network protocols.

What is claimed is:

1. A non-transitory computer readable memory comprising instructions that when executed on a processor:
receive a request message from a source code editor including a location in an HLS design file and an autocompletion request, the HLS design file including at least one HLS command,
identify zero or more tokens for the request, and
generate a response message containing at least one of:
a description corresponding to the zero or more tokens,
a list of valid HLS commands,
a proper HLS syntax prompt, and
a prompt for an HLS pragma.

2. The non-transitory computer readable memory of claim 1 comprising instructions that when executed on the processor:
identify an HLS command token in the line of source code as part of the request message, and
generate the response message to include the HLS command token and a list of zero or more required arguments.

3. The non-transitory computer readable memory of claim 1, wherein:
the zero or more tokens includes one token comprising a hash character, and
the response message contains the prompt for the HLS pragma.

4. The non-transitory computer readable memory of claim 1, wherein:
the HLS design file contains C or C++ code, and
comprising instructions that when executed on the processor:
identify a pragma token followed by an HLS token, and
identify a partial HLS pragma token following the HLS token, and
generate the response message includes identifying a subset of the list of valid HLS commands matching the identified partial HLS command token.

5. The non-transitory computer readable memory of claim 1, wherein the identified zero or more tokens includes a valid HLS command that requires a program variable, the computer readable memory comprising instructions that when executed on a processor:
identify a list of program variables defined in the HLS design file, and
append the proper HLS syntax prompt with the list of valid options.

6. The non-transitory computer readable memory of claim 5, wherein the valid HLS command requires the parameter argument to be of one or more allowed parameter types, the computer readable memory comprising instructions that when executed on a processor:
eliminate from the list of defined parameters all parameters not matching the allowed parameter types.

7. The non-transitory computer readable memory of claim 1 comprising instructions that when executed on a processor:
identify a syntax error and send the response message to include an error message.

8. A non-transitory computer readable memory comprising instructions that when executed on a processor:
establish a socket connection with a source code editor,
receive over the socket connection an edit notification referencing an HLS design file,
parse a first line of the HLS design file to generate a first list of tokens,
identify one of the first list of tokens as an HLS command,
identify an error in the first list of tokens,
include an error message in a diagnostics list, and
send the diagnostics list over the socket to the source code editor.

9. The non-transitory computer readable memory of claim 8 comprising instructions that when executed on the processor:
identify the HLS command as an invalid command, and
include a valid HLS command suggestion in the diagnostics list.

10. The non-transitory computer readable memory of claim 8 comprising instructions that when executed on the processor:
retrieve an expected number of parameters for the HLS command,
determine the first list of tokens contains fewer than the expected number of parameters for the HLS command, and
include an incomplete command message in the diagnostics list.

11. The non-transitory computer readable memory of claim 8 comprising instructions that when executed on the processor:
determine the first list of tokens contains an invalid parameter for the HLS command, and
include an invalid parameter message in the diagnostics list.

12. The non-transitory computer readable memory of claim 8 comprising instructions that when executed on the processor:
determine the first list of tokens contains a parameter of an invalid type for the HLS guidepost, and
include an invalid parameter type message in the diagnostics list.

13. The non-transitory computer readable memory of claim 8 comprising instructions that when executed on the processor:
parse each remaining non-empty line of the HLS design file.

14. The non-transitory computer readable memory of claim 8, wherein the error message includes a line number in the HLS design file.

15. A non-transient, computer readable memory comprising instructions that when executed on a processor:
receive a request message from a source code editor including a location specifying a line number and a character number within an HLS design file, the HLS design file including at least one HLS command,
retrieve a line of source code from the HLS design file at the specified line number,
tokenize the retrieved line of source code from the HLS design file,
identify a token in the tokenized line of source code corresponding to the character number, and
generate a response message containing a description of the identified token.

16. The non-transient, computer readable memory of claim 15 comprising instructions that when executed on the processor:
determine the request message indicates a hover request, and
including documentation of the identified token in the response message.

17. The non-transient, computer readable memory of claim 15 comprising instructions that when executed on the processor:
determine the identified token is a hash character, and
including a prompt for an HLS pragma in the response message.

18. The non-transient, computer readable memory of claim 15 comprising instructions that when executed on the processor:
identify the token is a partial HLS command,
identify a list of valid HLS guidepost matching the partial HLS command, and
include the list of matching HLS commands in the response message.

19. The non-transient, computer readable memory of claim 15 comprising instructions that when executed on the processor:
determine the token is an HLS command that requires a parameter,
identify a match list of program variables defined in the HLS design file, and
include the match list in the response message.

20. The non-transient, computer readable memory of claim 19 comprising instructions that when executed on the processor:
determine the required parameter is designated to be a specified type, and
exclude from the match list of program variables any program variable with a type different than the specified type.
